(19) United States
(12) Patent Application Publication
(10) Pub. No.: US 2010/0108919 A1
(43) Pub. Date: May 6, 2010

(54) OPTICAL SENSOR CHIP AND JAMMING PROTECTION DEVICE COMPRISING SUCH A CHIP

(76) Inventor: Bernhard Sofaly, Deutsch Wagram (AT)

Correspondence Address: King & Spalding LLP, 401 Congress Avenue, Suite 3200, Austin, TX, 78701, US

(21) Appl. No.: 12/532,600

(22) PCT Filed: Feb. 14, 2008
(86) PCT No.: PCT/EP08/51770

§ 371 Date: Sep. 22, 2009

(30) Foreign Application Priority Data
Mar. 23, 2007 (DE) 10 2007 014 034.9

(51) Int. Cl. G01J 1/42; H01L 31/12; G01J 1/00

(52) U.S. Cl. 250/552; 250/208.2; 356/213

(57) ABSTRACT

An optical sensor chip, especially for an optical jamming protection device has a one-dimensional or two-dimensional array of photo-sensitive elements, especially photodiodes, a number of pre-processing switching circuits for respectively processing a detection signal of each element, and a programmable interface between the array and the pre-processing switching circuits, a pre-processing switching circuit being associable with each element by the interface. An optical jamming protection device has an emitter unit which is designed in such a way as to emit radiation in a spatial area, a detector unit for detecting a radiation field from the spatial area, and a control unit designed to identify an obstacle in a pre-determined monitoring region in the spatial area, by evaluating output signals of the detector unit. To this end, the detector unit comprises an above-mentioned sensor chip.

### CROSS-REFERENCE TO RELATED APPLICATIONS

This application is a U.S. National Stage Application of International Application No. PCT/EP2008/051770 filed Feb. 14, 2008, which designates the United States of America, and claims priority to German Application No. 10 2007 014 034.9 filed Mar. 23, 2007, the contents of which are hereby incorporated by reference in their entirety.

### TECHNICAL FIELD

The invention relates to an optical sensor chip. The invention also relates to an optical jamming protection (anti-trap) device, particularly for monitoring a window, sliding door or tailgate in a motor vehicle, having such a sensor chip.

### BACKGROUND

Anti-trap devices have hitherto employed, on the one hand, light barriers which can detect an obstacle on the connecting line between a transmitter and a receiver. The receiver is designed to receive a signal from the transmitter during normal operation and, if an obstacle is present in the monitored area, to detect the presence of the obstacle on the basis of a diminution or collapse of the incoming signal at the receiver.

To embody a flat monitored area, the transmitter and receiver of a light barrier can be embodied linearly and positioned along the edges of the monitored surface. The disadvantage of this is the necessity, in design terms, to frame such a monitored surface with transmitter-receiver systems. Also, if a curved or irregularly shaped surface region is to be monitored, there is also increased design complexity for embodying such transmitter-receiver systems in which a transmitter and a receiver or a transceiver unit and a reflector must be opposite one another on a straight line.

On the other hand, anti-trap devices are implemented using sensors with transceiver systems based on reflection of a signal by the obstacle to be detected, similar to the radar or echo sounding principle. The receiver of such a system is designed to identify an obstacle by the thereby backscattered or reflected components of a signal from the transmitter.

Document DE 696 34 151 T2 discloses an optical anti-trap system using a sensing method based on the reflection of infrared light. The intensity of the infrared radiation reflected back from an obstacle is measured. An obstacle is detected on the basis of an increase in the intensity of this radiation reaching the receiver. However, this system has been found to be disadvantageous in that the monitored area cannot be sufficiently well adapted to curved surfaces in order to map a vehicle contour, for example. Moreover, the known system is prone to temperature fluctuations and also to received background radiation affecting the measurement. The system comprises one or more sensor chips each incorporating a photodiode and a downstream circuit for pre-processing the detection signal produced by the photodiode.

### SUMMARY

According to various embodiments, a sensor chip particularly suitable for an optical anti-trap device can be specified. According to other embodiments, a particularly suitable optical anti-trap device can be specified.

According to an embodiment, an optical sensor chip, particularly for an optical anti-trap device, comprises a one- or two-dimensional array of photosensitive elements, particularly photodiodes, a number of pre-processing circuits for processing a detection signal for a respective element, and a programmable interface between the array and the pre-processing circuits, a pre-processing circuit being assignable to each element by means of the interface.

According to a further embodiment, the array of photosensitive elements can be two-dimensional, the number of pre-processing circuits may correspond to the number of rows or the number of columns in the array, and an element from a row or column of the array can be assignable to one correlation circuit in each case.

According to another embodiment, an optical anti-trap device may comprise an emitter unit which is set up to emit radiation into a spatial region, a detector unit which is set up to detect a radiation field from the spatial region, and a control unit which is embodied to detect an obstacle in a predefined monitored area in the spatial region by evaluating output signals of the detector unit, said detector unit comprising a sensor chip as described above.

According to a further embodiment, the detector unit may comprise a mapping optical system preceding the sensor chip in the direction of incidence of light. According to a further embodiment, the control unit may be embodied for pulsed control of the emitter unit. According to a further embodiment, the emitter unit may comprise a number of light-emitting diodes and/or a number of laser diodes. According to a further embodiment, the emitter unit may comprise an optical system for forming an essentially fan-shaped beam, in particular a lens with locally cylindrical surface shape. According to a further embodiment, to detect an obstacle in the monitored area, the control unit may be embodied to detect a spatially inhomogeneous change over time in the intensity of the radiation field on the basis of a comparison of the output signals of different photosensitive elements of the array.

### BRIEF DESCRIPTION OF THE DRAWINGS

Exemplary embodiments will now be discussed in greater detail with reference to the accompanying drawings in which:

FIG. 1 is a block diagram illustrating an optical anti-trap device with an optoelectronic module, comprising an emitter unit and a detector unit, and having a control unit,

FIG. 2 is a perspective view illustrating a first embodiment of the anti-trap device, wherein a sensor peripheral board incorporating the control unit is disposed parallel to and abutting a sensor surface of the optoelectronic module,

FIG. 3 shows in a representation according to FIG. 2 an alternative embodiment of the anti-trap device in which the sensor peripheral board abuts the optoelectronic module orthogonally with respect to the sensor surface,

FIG. 4 shows a detailed perspective view of the optoelectronic module, and

FIG. 5 shows a detailed perspective view of a version of the detector unit with a programmable sensor chip.

Mutually corresponding parts and variables are provided with the same reference characters throughout the figures.

### DETAILED DESCRIPTION

According to various embodiments, the sensor chip comprises a one- or two-dimensional array of photosensitive elements, particularly photodiodes, i.e. a plurality of such elements which are disposed in a predefined geometrical arrangement in particular on a common substrate. The sensor chip also comprises a number of integrated pre-processing circuits, each pre-processing circuit being set up to independently pre-process a detection signal of a photodiode of the array. A mutual assignment of photodiodes and pre-processing circuits is flexibly selectable or adjustable by means of a programmable interface interposed between the photodiode array and the circuits, namely by programming of the interface. The interface is preferably embodied such that a single (in particularly any) photodiode is always uniquely assignable to a pre-processing circuit. Alternatively, however, the interface can also be embodied such that a plurality of photodiodes connected in parallel can be assigned to a common pre-processing circuit.

Pre-processing includes one or more pre-processing steps with which the output signal of the assigned photodiode is prepared for subsequent evaluation in the control unit. Pre-processing comprises in particular—individually or in any combination—analog-digital conversion, measured value storage, amplification or time accumulation of the output signal.

Accumulation therefore means summation of the output signal of the assigned photodiode over a predefined number of measurement cycles. The accumulation thus basically corresponds to an exposure time setting.

The various embodiments are based on the consideration that for the majority of applications, not all the photodiodes of an array are required. In the case of an anti-trap device for a motor vehicle window lift, the monitored area is generally constituted by a surface essentially parallel to the optical axis of the detector unit. Such a monitored area is mapped into an essentially one-dimensional image area, i.e. a more or less wide line on the photodiode array, said image area being mostly curvilinear according to the geometry of the monitored space. On the other hand, the monitored area, and therefore also the image area are generally different for each specific application of the anti-trap device, i.e. for the type of vehicle for which the device is to be used, for example. In order to enable the device to be used for as many applications as possible without having to manufacture custom products, it is known to make sense in terms of rational production to provide the photodiode array with a sufficiently amply dimensioned photodiode arrangement which covers the image areas of the monitored areas considered to be for normal applications. However, for the individual application, such a standard array is generally overdimensioned so that a considerable number of photodiodes are superfluous, particularly at the edges of the array, as they are outside the image area. It is known that this overdimensioning would have a particularly disadvantageous effect if each photodiode of the array were assigned its own pre-processing circuit, especially as this would significantly increase the size of the sensor chip. This would again reduce the utilizability of the device, e.g. in respect of the limited amount of available space in motor vehicles, and make it more expensive to manufacture such a sensor chip.

In this area of conflicting requirements, a synthesis is achieved by the above described embodiment. The possibility of being able to assign photodiodes and pre-processing circuits to one another in a flexible manner by means of programming obviates the need to provide a separate pre-processing circuit for each photodiode. Instead, it is enough to incorporate on the sensor chip a sufficiently large number of pre-processing circuits, but one that is generally much lower than the number of photodiodes, to which the relevant photodiodes can then be selectively assigned for scanning the monitored area in the specific application, thereby simultaneously enabling both an inexpensive and space-saving implementation of a nevertheless versatile sensor chip.

By pre-processing the output signals of the photodiodes directly on the sensor chip, a particularly favorable signal-to-noise ratio is also achieved.

In the case of a two-dimensional array with a rectangular photodiode arrangement comprising a number of rows and a number of columns, it is preferable to provide a number of pre-processing circuits corresponding to the number of rows or columns, one photodiode from each row or column of the array being uniquely assignable to a pre-processing circuit. In respect of the anti-trap device, according to various further embodiments, the device comprises an emitter unit configured to emit radiation into a spatial region and a detector unit set up to detect a radiation field from the spatial region. The device also comprises a control unit designed to detect an obstacle in a predefined monitored area in the spatial region by analyzing output signals of the detector unit. For this purpose the detector unit contains a sensor chip of the above mentioned type.

The control unit is constituted in particular by one or more software modules which are implemented on one or more hardware modules, particularly microcontrollers or the like. The photodiode array is here preferably preceded by a mapping optical system. The term mapping optical system is to be taken to mean an optical component, e.g. a lens, a mirror or the like, or an arrangement of a plurality of such components, which in turn maps the light rays incident on the optical system from a spatial point to a defined point of an image space.

As a mapping optical system precedes a photodiode array, each point in the monitored area is unambiguously mapped to an image point in the environment of the sensor chip, where it is detected by the photodiode array in a location-selective manner. This enables characteristic variables of an incident radiation field—the intensity, for example—to be differentiated as a function of the angle of incidence. The design of the device therefore enables the monitored area to be spatially segmented by mapping light beams from different spatial segments of the monitored area to different diodes in the array and to be detectable independently of these diodes. In the widest scope of the invention, the array comprises at least two, but preferably a much larger number of photodiodes. That is to say, the resolution of the spatial segmentation depends on the number and density of photodiodes on the array. The more densely the photodiodes are disposed on the array and the greater the number of photodiodes, the finer the segmentation and the higher the resolution of the characteristic variables of an incident radiation field according to the angle of incidence.

Compared to separate photodiodes each mounted in a separate diode housing, a photodiode array can have a relatively high number and density of photodiodes, e.g. in the form of a segmented photosensitive layer.

According to this design principle, it is therefore possible to identify correspondingly precisely the angle of incidence of an arriving light pulse using a photodiode array of this kind and a mapping optical system positioned upstream thereof. Using a mapping optical system, e.g. a convex lens, has the additional advantage that the light reflected by an obstacle is collimated perpendicularly to the optical axis of the optical system in both dimensions, thereby enabling a comparatively large amount of light to be concentrated by means of a comparatively small lens.

In an embodiment of the anti-trap device, the control unit is designed to control the emitter unit.

Controlling the emitter unit by means of the control unit initially makes it possible for the emitter unit to be activated only when an increased probability of trapping has been verified e.g. by other means, or this probability is increased by system states per se. For a vehicle window, for example, optical anti-trap protection only needs to be active when the window is being closed, is still open and is less than a predefined minimum distance from the closed position, but not in the steady closed state, or when the window is being opened.

The emitter unit is preferably controlled in a pulsed manner. Pulsed control of the emitter unit makes it possible for reference signals with a specific signature, e.g. with a specific intensity modulation, to be radiated via the emitter unit which are identified and classified accordingly by the detector unit so that interfering effects—such as received background radiation—can be masked out. For signal identification, the control unit thus acts as an electronic interface between the control unit and the detector unit. In another embodiment of the optical anti-trap device, the emitter unit comprises a number of light-emitting diodes or a number of laser diodes which preferably radiate in the infrared region.

In a suitable development of the optical anti-trap device, the emitter unit comprises an optical system for directed radiation so that the spatial region captured by the emission field can be limited in advance to the extent that both the predefined monitored area is completely captured and the discrepancy between the spatial region captured and the monitored area is as small as possible. Focusing of the emission field is advisable in order to minimize the energy and processing required.

In particular, said optical system, which in this embodiment is preferably implemented in the form of a cylindrical lens, is designed to produce an essentially fan-shaped beam. In order to detect an obstacle in a monitored area, the control unit is also advantageously embodied to capture a spatial intensity distribution of the incident radiation field from the spatial region which deviates from a predefined reference pattern—i.e. varies as a function of the angle of incidence—or a spatially inhomogeneous change in intensity over time by comparing the output signals of different photodiodes in the array. Defined as a spatially inhomogeneous intensity change is a change over time in the light radiation incident on the photodiode array, said light radiation differing from one spatial region of the photodiode array to another, i.e. in particular for different photodiodes of the array. This criterion is met in particular if the light intensities registered for different photodiodes change simultaneously in a significant non-proportional manner. The radiant intensity—or amplitude, the square of the absolute value of which is proportional to the radiant intensity—measured at a photodiode is not evaluated absolutely, but comparatively in relation to the intensities incident on the other photodiodes. The respective intensities determine the current strengths of the output signals of the respective photodiodes, which are further processed for the evaluation.

On the one hand, said comparative intensity evaluation makes the anti-trap device independent of the absolute received light intensity and therefore independent of the illumination energy. The sensitivity of the device to absolute brightness fluctuations and temperature-dependently varying operating behavior of the emitter unit and the detector unit is therefore effectively reduced.

On the other hand, the capturing of spatially inhomogeneous intensity changes allows better differentiation of locally delimited obstacles, such as a hand held in the closing path of a vehicle window, from interfering effects such as a sudden change in background brightness. Thus it is characteristic of a steady-state illumination determined by environmental conditions, or rather of the received background radiation, that the radiation intensity essentially varies in a spatially homogeneous manner over time. However, a spatially limited moving obstacle in the monitored area induces a spatially in-homogeneous change over time in the radiation conditions, resulting in a variable, non-proportional change over time in the registered intensity on different photodiodes of the array. The higher the resolution of the spatial segmentation, the more demonstrable this effect becomes for smaller obstructing objects.

The comparative intensity evaluation has a particularly advantageous effect on reliable detection of comparatively small and/or weakly reflecting obstructing objects, the influence of which may be easily concealed by powerful received background radiation in the case of absolute evaluation of the radiation detected in the detector unit, causing it to be overlooked.

The comparative intensity evaluation is consequently an effective aid for differentiating changes over time of the received background radiation per se from changes over time in the radiation field that are caused by a moving obstacle in the monitored area and therefore for better detecting a possible obstacle scenario even under unfavorable lighting conditions.

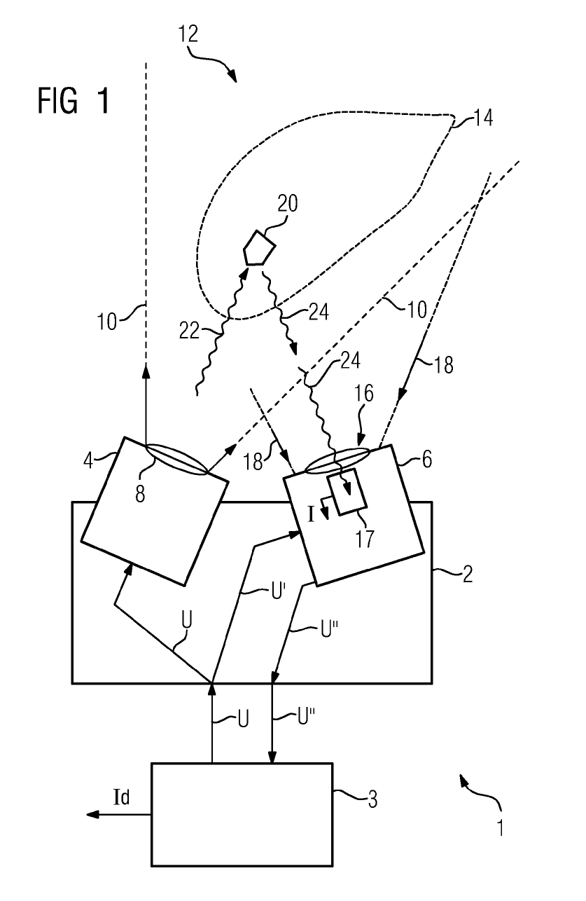

FIG. 1 schematically illustrates an optical anti-trap device 1 used as part of a power window for a motor vehicle.

The device 1 comprises an optoelectronic module 2 and a control unit 3. The control unit 3 in turn comprises an emitter unit 4 and a detector unit 6.

A fan-shaped beam 10 is radiated into a spatial region 12 by the emitter unit 4 with the aid of a focusing optical system 8. Inside the spatial region 12, a monitored area 14 is defined within which intruding objects are to be detected as obstacles.

The detector unit 6 comprises a mapping optical system 16 and a sensor chip 17 disposed downstream of same in the direction of incidence of light. By means of the mapping optical system 16, a (light) radiation field 18 incident from the spatial region 12 is mapped onto the sensor chip 17. The radiation field 18 contains reflected components of the beam 10 and components of received background radiation coming from the spatial region 12.

If an obstacle 20 is in the spatial region 12, a light pulse 22 of the beam 10 radiated by the emitter unit 4 strikes the obstacle 20 and is scattered by same, a component 24 of the light pulse 22 being radiated back to the detector unit 6.

The light pulse 22 and therefore also its radiated-back component 24 have a short-time-scale intensity modulation as a signature, so that the detector unit 6 can identify the component 24 in the incident radiation field 18 with a uniform or, at the most, long-time-scale-varying received background radiation. The component 24 is directed by the mapping optical system 16 onto the sensor chip 17 where it is detected.

The control unit 3 triggers the emitter unit 4 by means of a modulation voltage U to emit periodically intensity-modulated light pulses whose signature is determined by the modulation voltage U. In addition, the modulation voltage U is transmitted to the detector unit 6 as reference variable U′. The detector unit 6 processes (in the manner described in greater detail below) a detection signal I corresponding to the detected radiation component 24 with the reference variable U′ and forwards a resulting detector output signal U″ to the control unit 3. This contains information about the amplitude and therefore the radiant intensity of the radiated-back component 24 between the emitter unit 4 and the detector unit 6, as well as information about the direction of incidence of the component 24. On the basis of the detector output signal U″, the control unit 3 determines the distance and position of the obstacle 20 and verifies whether the obstacle 20 is in the predefined monitored area 14. If this is the case, the control unit 3 transmits an identification signal Id to other devices, e.g. a window lift controller, which then stop or reverse the motion of the power window.

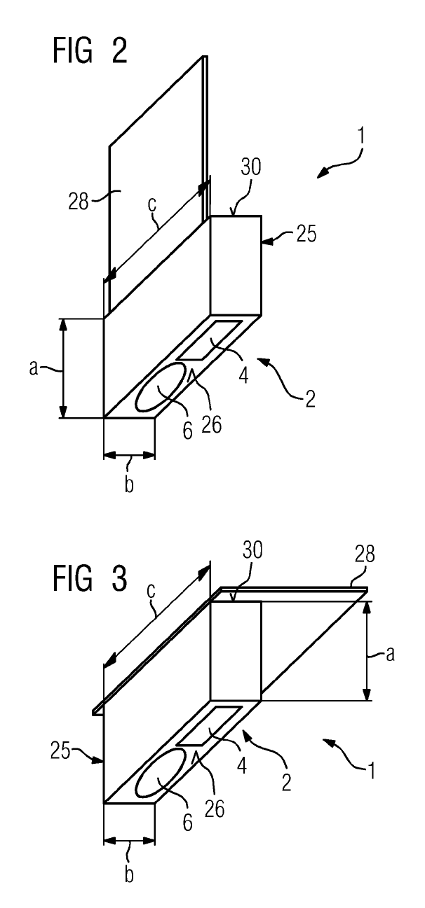

As shown in FIG. 2, the optoelectronic module 2 has an essentially cuboidal housing 25 with the emitter unit 4 and the detector unit 6 protruding with their respectively assigned optical systems 8 and 16 from a side of the housing 25 hereinafter referred to as the sensor surface 26. In the embodiment according to FIG. 2, the device 1 comprises, in addition to the module 2, a sensor peripheral board 28 which comprises at least parts of the control unit. In this embodiment the sensor peripheral board 28 is aligned parallel to the sensor surface 26 and disposed abutting an opposite side 30 of the housing 25.

In a preferred dimensioning, the housing 25 has a height a of 25 mm, a width b of 10 mm, and a length c of approximately 50 mm. With these compact dimensions of the optoelectronic module 2, the device 1 is suitable for the stated use as a power window anti-trap system in a vehicle. The anti-trap system 1 is here mounted with the abutting sensor peripheral board 28 on a substrate that is fixed with respect to the vehicle window.

The embodiment shown in FIG. 3 of the device 1 is of essentially identical construction to the above described type, but differs from the latter in that the sensor peripheral board 28 is aligned orthogonally with respect to the sensor surface 26 of the module 2, and therefore protrudes approximately perpendicularly from the side 30 of the housing 25.

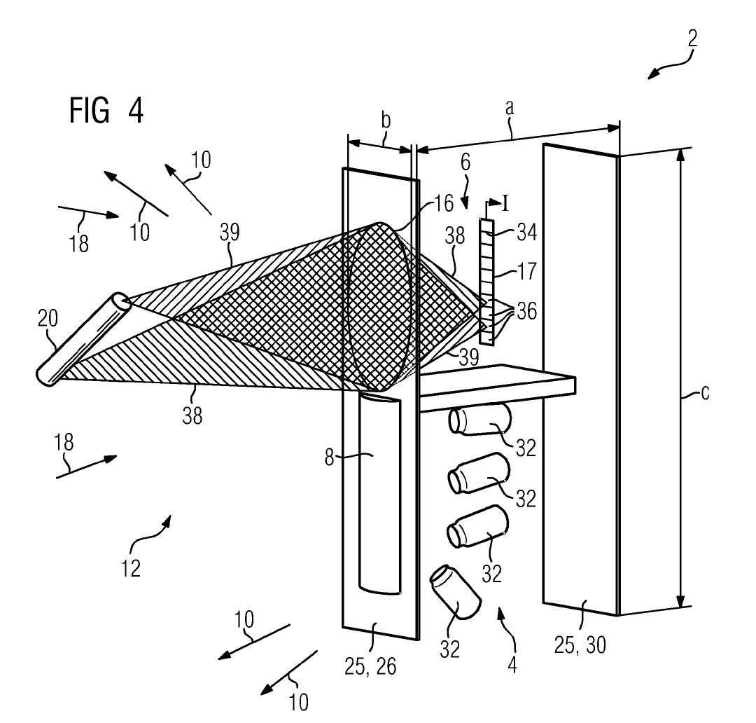

FIG. 4 shows the optoelectronic module 2 in greater detail than in FIG. 1. Visible here are the two housing sidewalls of the module 2 spaced apart by the height a which correspond to the sensor surface 26 and the opposite side 30. The other sidewalls of the housing 25 are not shown here in order to enable components inside the optoelectronic module 2 to be made visible. In this illustration it can be seen that the emitter unit 4 comprises a number of light-emitting diodes 32 which are aligned such that, by means of the focusing optical system 8 embodied in the form of a cylindrical lens, they scatter the light emerging from the light-emitting diodes 32 into the fan-shaped beam 10.

As shown in FIG. 4, the mapping optical system 16 of the detector unit 6 is constituted by a convex lens. The sensor chip 17 here comprises a one-dimensional array 34 of photodiodes 36.

The drawing shows the beam paths 38 and 39 which, from a respective end point of an obstacle 20 shown here as a longish object in the spatial region 12, are incident via the optical system 16 on different photodiodes 36 in each case.

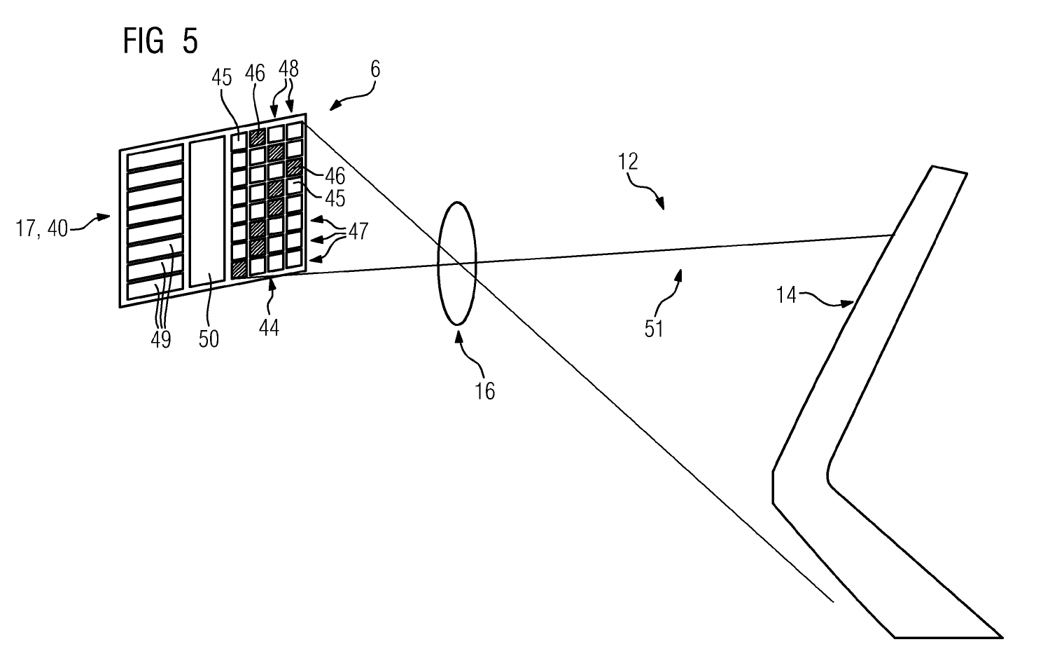

FIG. 5 shows an embodiment of the detector unit 6 in which a programmable sensor chip 40 is provided. The sensor chip 17 here comprises—at variance with FIG. 4—an array 44 of photodiodes 45,46 that are disposed in rows 47 and columns 48 in the form of a two-dimensional matrix. The array 44 is preceded by a number of pre-processing circuits 49, the number of pre-processing circuits 49 corresponding to the number of rows 47 in the array 44. A programmable interface 50 assigns a photodiode 46 from each of the rows 47 to one of the pre-processing circuits 49 in each case. An output signal of such a photodiode 46 is therefore pre-processed in the correspondingly assigned pre-processing circuit 49 and transmitted to the control unit 3. The other photodiodes 45 of the array 44 are decoupled from the pre-processing circuits 49 by the configuring of the interface 49 so that the detection signals I of these photodiodes 45 are not processed further. The photodiodes 46 activated in this way form a one-dimensional contour on the two-dimensional array 44, with which, by virtue of the beam path 51 of the imaging optical system 16, the correspondingly contoured monitored area 14 in the spatial region 12 is defined.

The control unit 3 compares changes in the light intensities measured by the different photodiodes 46 with one another, and detects the presence of an obstacle 20 if it finds a significant change in light intensity that is spatially inhomogeneous, i.e. has not been detected by all the photodiodes 46 in the same or corresponding manner.

What is claimed is:

1. An optical sensor chip,
a one- or two-dimensional array of photosensitive elements,
a number of pre-processing circuits for processing a detection signal for a respective element, and
a programmable interface between the array and the pre-processing circuits, a pre-processing circuit being assignable to each element by means of the interface.

2. The sensor chip claim 1,
wherein
the array of photosensitive elements is two-dimensional,
the number of pre-processing circuits corresponds to the number of rows or the number of columns in the array, and
an element from a row or column of the array is assignable to one correlation circuit, respectively.

3. An optical anti-trap device, comprising:
an emitter unit which is set up to emit radiation into a spatial region,
a detector unit comprising a sensor chip according to claim 1 which is set up to detect a radiation field from the spatial region, and
a control unit which is embodied to detect an obstacle in a predefined monitored area in the spatial region by evaluating output signals of the detector unit.

4. The anti-trap device according to claim 3,
wherein the detector unit comprises a mapping optical system preceding the sensor chip in the direction of incidence of light.

5. The anti-trap device according to claim 3,
wherein the control unit is embodied for pulsed control of the emitter unit.

6. The anti-trap device according to claim 3,
wherein the emitter unit comprises at least one of a number of light-emitting diodes and a number of laser diodes.

7. The anti-trap device according to claim 3,
wherein the emitter unit comprises an optical system for forming an essentially fan-shaped beam.

8. The anti-trap device according to claim 3,
wherein, to detect an obstacle in the monitored area, the control unit is embodied to detect a spatially inhomogeneous change over time in the intensity of the radiation field on the basis of a comparison of the output signals of different photosensitive elements of the array.

9. The optical sensor chip according to claim 1, wherein the photosensitive elements are photodiodes.

10. The anti-trap device according to claim 3,
wherein the emitter unit comprises a lens with locally cylindrical surface shape.

11. An method for operating an optical sensor chip, comprising the steps of:
providing a one- or two-dimensional array of photosensitive elements,
processing a detection signal for a respective element by a number of pre-processing circuits, and
assigning a pre-processing circuit to each element by means of a programmable interface arranged between the array and the pre-processing circuits.

12. The method according to claim 11, wherein
the array of photosensitive elements is two-dimensional,
the number of pre-processing circuits corresponds to the number of rows or the number of columns in the array, and wherein
an element from a row or column of the array is assignable to one correlation circuit, respectively.

13. A method of operating an anti-trap device using the method for operating an optical sensor chip according to claim 11, comprising the steps of:
emitting radiation into a spatial region by an emitter unit,
detect a radiation field from the spatial region by said method for operating an optical sensor chip, and
evaluating output signals from said method for operating an optical sensor chip to detect an obstacle in a predefined monitored area in the spatial region.

14. The method according to claim 13, further comprising the step of:
providing a mapping optical system preceding the sensor chip in the direction of incidence of light.

15. The method according to claim 13,
wherein the radiation is emitted through a pulsed control of the emitter unit.

16. The method according to claim 13,
wherein the emitter unit comprises at least one of a number of light-emitting diodes and a number of laser diodes.

17. The method according to claim 13,
wherein the emitter unit comprises an optical system for forming an essentially fan-shaped beam.

18. The method according to claim 13,
wherein, to detect an obstacle in the monitored area, the method comprises the step of detecting a spatially inhomogeneous change over time in the intensity of the radiation field on the basis of a comparison of the output signals of different photosensitive elements of the array.

19. The method according to claim 11, wherein the photosensitive elements are photodiodes.

20. The method according to claim 13,
wherein the emitter unit comprises a lens with locally cylindrical surface shape.
